(19) United States
(12) Patent Application Publication
(10) Pub. No.: US 2018/0199453 A1
(43) Pub. Date: Jul. 12, 2018

(54) ELECTRONICS ENCLOSURE

(71) Applicant: WHISKER LABS, INC., GERMANTOWN, MD (US)

(72) Inventor: Ryan Linderman, Oakland, CA (US)

(21) Appl. No.: 15/867,560

(22) Filed: Jan. 10, 2018

Related U.S. Application Data
(60) Provisional application No. 62/444,719, filed on Jan. 10, 2017.

(51) Int. Cl. H05K 5/02; H05K 5/03; H05K 5/06

(52) U.S. Cl. CPC H05K 5/0204; H05K 5/069; H05K 5/03; H05K 5/0213

(57) ABSTRACT

An apparatus for thermal management and protection from moisture for an electronic device is described. The apparatus comprises an internal enclosure insert containing a printed circuit board (PCB) populated with at least one electrical component; a back plate coupled to the internal enclosure insert, wherein the back plate is coupled along an internal surface to at least one electrical component on the PCB; and a thermal radiation shield coupled to and surrounding the internal enclosure insert, at least one portion of the thermal radiation shield being separated from the internal enclosure insert by at least one air gap. When affixed to a mounting surface, at least one air gap is formed between the thermal radiation shield and the mounting surface.

### RELATED APPLICATIONS

This application claims priority to U.S. Provisional Patent Application No. 62/444,719, filed on Jan. 10, 2017, which is incorporated herein by reference.

### TECHNICAL FIELD

This application relates generally to an electronics enclosure for use in installing and operating electronics, particularly printed circuit boards (PCB) and printed circuit board assemblies (PCBA), in outdoor environments or locations with high levels of precipitation and/or thermal radiation.

### BACKGROUND

Typically, the installation of electronic components in locations that are susceptible to precipitation, condensation, and/or thermal radiation—such as applications such as electrical sensors and monitoring systems installed on outdoor utility panels, outdoor power converters and telecommunications equipment as well as electronics exposed to high temperature processes in industrial environments—is done by housing the electronic components in a sealed enclosure affixed to a wall or other hard surface to prevent potentially damaging moisture and heat from reaching the components. FIG. 1 is an example of a conventional sealed enclosure 101 known in the art. As shown in FIG. 1, the enclosure 101 surrounds a PCBA 102. Because the enclosure is affixed to a wall, air convection occurs around the exterior surface (i.e., Surface 1) of the enclosure and thus does not reach the interior of the enclosure where the PCBA is located. Additionally, if thermal radiation or sunlight is incident on the outer surface, the enclosure wall is heated which increases the temperature inside the enclosure and raises the temperature of the electronics.

However, the configuration of the conventional enclosure 101 of FIG. 1 presents several problems with respect to the operation of the electronic components contained within. Due to its sealed design, the interior of the enclosure 101 may reach undesirable operating conditions (e.g., if located in an environment subject to high temperatures) that can result in damage to or malfunction of the electronic components. Also, the electronic components within these enclosures are typically coupled to other devices via cable, and such enclosures do not adequately manage excess cable lengths to reduce clutter and improve system appearance while keeping the flexibility to accommodate sites with both long and short cable runs.

### SUMMARY

Therefore, what is needed is an improved electronics enclosure that addresses the above shortcomings to protect sensitive electronics that are installed in a variety of indoor and outdoor locations from exposure to environmental conditions that would undesirably affect the operation of the electronics and to increase the flexibility of connecting the electronics enclosure to other devices with cables of varying lengths.

The invention, in one aspect, features an apparatus for thermal management and protection from moisture for an electric device, comprising: an internal enclosure insert containing a printed circuit board (PCB) populated with at least one electrical component; a back plate coupled to the internal enclosure insert with an air gap to a mounting surface wall, wherein the back plate is coupled along an internal surface to at least one electrical component on the PCB; and a thermal radiation shield coupled to and surrounding the internal enclosure insert, at least one portion of the thermal radiation shield being separated from the internal enclosure insert by at least one air gap; wherein, when affixed to the mounting surface wall, at least one air gap is formed between the thermal radiation shield and the mounting surface.

The above aspect can include one or more of the following features. In some embodiments, the back plate is thermally conductive. In some embodiments, the back plate comprises at least one of: copper sheet metal or aluminum. In some embodiments, the back plate is thermally insulating. In some embodiments, the back plate comprises plastic. In some embodiments, a heat spreader is placed on an interior surface of the plastic back plate. In some embodiments, the heat spreader comprises at least one of: copper sheet metal or aluminum. In some embodiments, the back plate is thermally coupled to the at least one electrical component on the PCB.

In some embodiments, the internal enclosure insert contains a perimeter region around which a length of one or more cables is secured. In some embodiments, the one or more cables connect the PCB to one or more external devices. In some embodiments, the air gaps are sufficiently large to allow buoyancy induced natural convection. In some embodiments, wherein the back plate is coupled to the PCB by a thermal adhesive.

In some embodiments, the apparatus is part of an electrical energy monitoring system. In some embodiments, the apparatus is part of an outdoor telecommunications system. In some embodiments, the apparatus is part of an outdoor power conversion system. In some embodiments, the apparatus is part of an outdoor LED light fixture.

Other aspects and advantages of the invention will become apparent from the following detailed description, taken in conjunction with the accompanying drawings, illustrating the principles of the invention by way of example only.

### BRIEF DESCRIPTION OF THE DRAWINGS

The advantages of the invention described above, together with further advantages, may be better understood by referring to the following description taken in conjunction with the accompanying drawings. The drawings are not necessarily to scale, emphasis instead generally being placed upon illustrating the principles of the invention.

FIG. 1 is a diagram of an exemplary electronics enclosure as known in the art.

FIG. 2 is a diagram of a front view and a back view of an electronics enclosure, according to an embodiment of the invention.

FIG. 3 is a diagram of a cross-section view of the electronics enclosure, according to an embodiment of the invention.

FIG. 4 is a diagram of a cross-section view of the electronics enclosure showing air convection with respect to the enclosure, according to an embodiment of the invention.

FIG. 5 is a diagram of a cross-section view of the electronics enclosure including a heat spreader on the back plate, according to an embodiment of the invention.

FIG. 6 is a diagram of a partial inner view of the electronics enclosure showing the electronics insert and a side view of the electronics insert, according to an embodiment of the invention.

FIG. 7 is an exploded view of the electronics enclosure, according to an embodiment of the invention.

### DETAILED DESCRIPTION

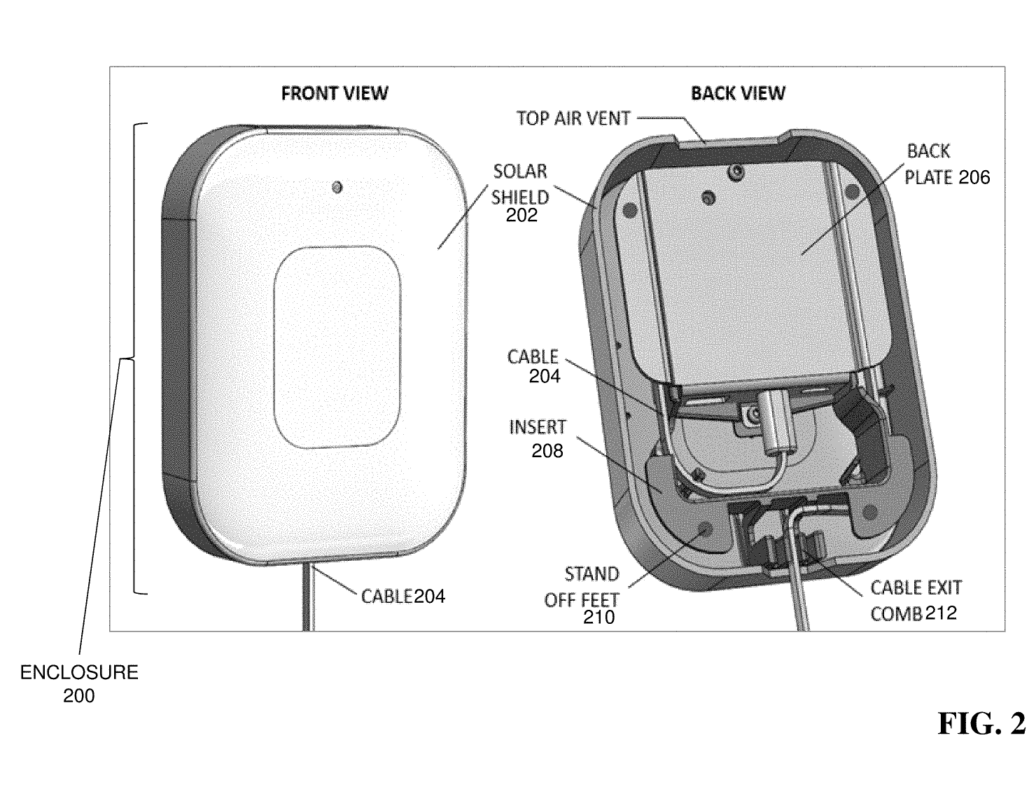

FIG. 2 is a diagram of a front view and a back view of an electronics enclosure 200, according to an embodiment of the invention. The enclosure 200 is designed to house a printed circuit board (PCB)/printed circuit board assembly (PCBA) and protect it from the high temperatures associated with direct sunlight and to prevent water intrusion from rain and water sprays. For convenience, the remainder of the disclosure refers to a PCBA but it should be appreciated that other types of electronics can be configured within the enclosure described herein.

As shown in FIG. 2, the enclosure includes a solar shield 202, a cable 204 coupled to the PCBA (not shown), a back plate 206 affixed to the PCB, a PCBA insert 208 that houses the PCBA, stand-off feet 210 maintain a gap to the mounting surface or wall, and a cable exit comb 212 for holding the cable in place as it exits the enclosure. Additionally, the cable 204 traverses a perimeter of the insert 208 before exiting at the bottom of the enclosure; it should be appreciated that in some embodiments, the cable 204 can traverse the perimeter multiple times before exiting. Also, although FIG. 2 depicts only one cable, it should be appreciated that the enclosure can be configured to accommodate a plurality of cables that are each connected to the PCBA.

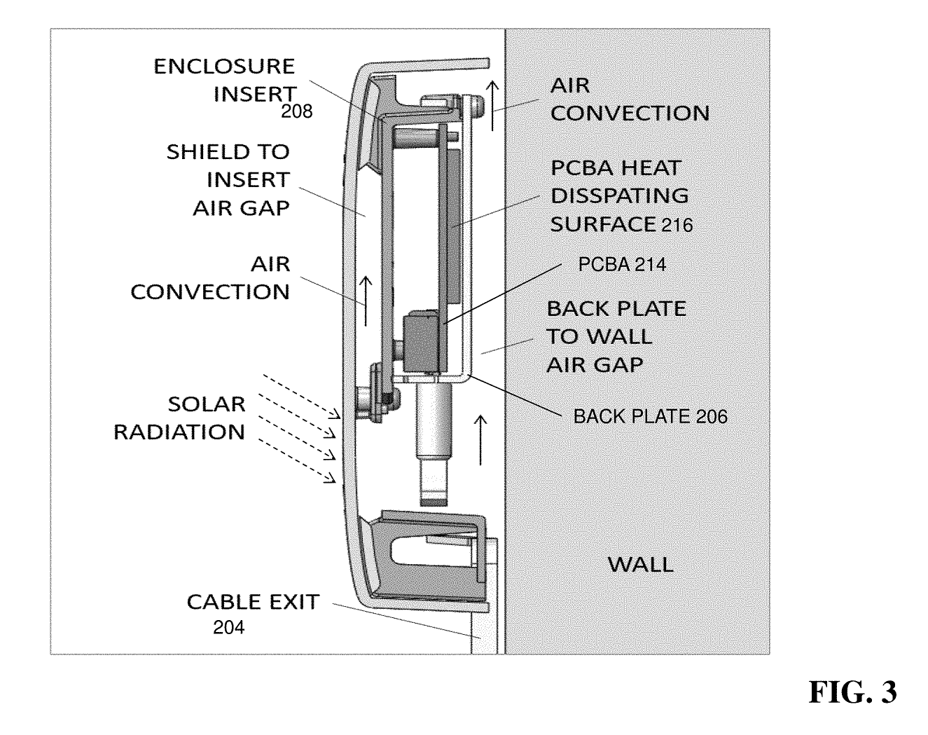

The solar shield 202 creates a thermally isolated surface from the insert 208, with the capability for air to circulate on both sides of the shield 202 to increase heat dissipation of incident solar radiation to the ambient environment rather than coupling it to the PCBA insert enclosure. FIG. 3 is a diagram of a cross-section view of the electronics enclosure 200, according to an embodiment of the invention. As shown in FIG. 3, the enclosure design includes a series of air gaps (e.g., an air gap between the shield and the insert, an air gap between the back plate and the wall, among others) that enable air convection (illustrated by the arrows) up through the interior of the electronics enclosure and out the top of the electronics enclosure. The enclosure of FIG. 3 also depicts the positioning of the PCBA 214 as well as a PCBA heat dissipating surface 216 coupled to the PCBA, which will be described in greater detail below.

The spacing of the gap between the insert 208 to the solar shield 202 is sufficient for natural convection to occur and allow heat to convect out of the top of the unit. Depending on the overall size of the insert 208, this gap is typically around 5-10 mm with ideally few contact points between the two walls so as to remain thermally isolated and to prevent obstructing weak natural convection air flows.

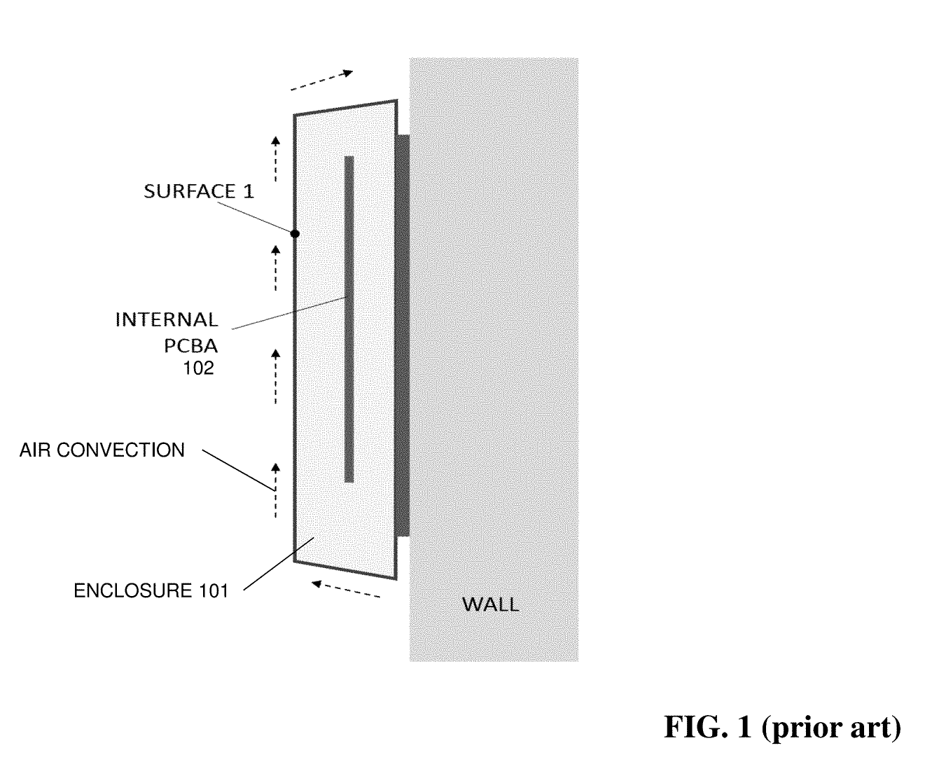

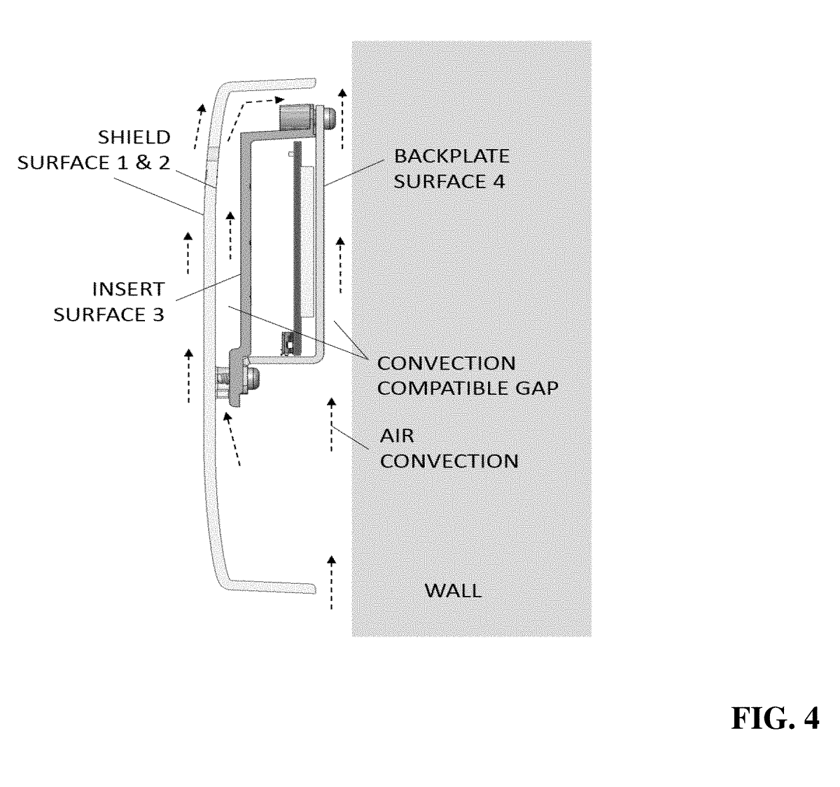

To provide additional thermal performance, the back plate 206 of the enclosure 200 can be made out of a thermally conductive material—such as aluminum or copper sheet metal—and act as both a heat spreader when coupled to heat dissipating devices on the PCBA 214, and as a convective heat sink to dissipate the heat to the air via the air gap between the solar shield 202 and the back plate 206 and the air gap between the back plate 206 and the mounting wall. FIG. 4 is a diagram of a cross-section view of the electronics enclosure showing air convection with respect to the enclosure, according to an embodiment of the invention. As shown in FIG. 4, air convection increases dramatically over the convection depicted for the enclosure 101 of FIG. 1. This advantageously creates several times the surface area for convective heat transfer compared to a single walled enclosure (e.g., the enclosure 101 of FIG. 1) attached to a mounting surface with only the front facing surface available for heat transfer. Due to the ˜4x increased heat transfer area of the enclosure 200, a similar reduction in thermal resistance is achieved—reducing the impact of incident solar radiation and keeping active electronic devices closer to ambient air temperatures. The stand-off feet 210 (as shown in FIG. 2) combined with fasteners such as attached magnets hold the enclosure 200 to the mounting wall with a defined air gap.

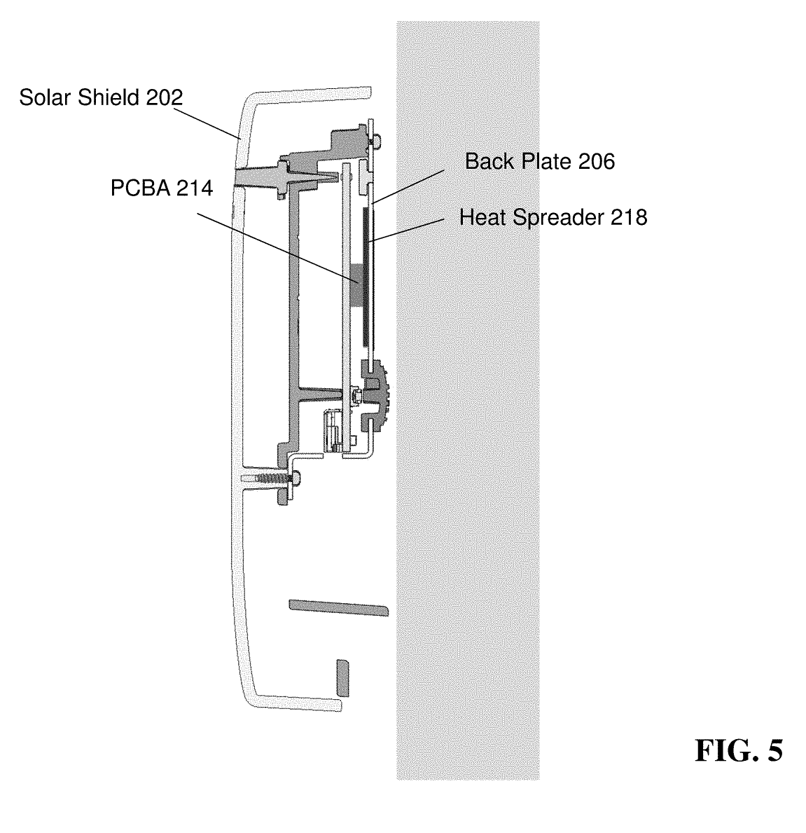

In some embodiments, the back plate 206 of the enclosure 200 can be made out of a thermally insulating material—such as plastic (e.g., polycarbonate (PC) or polyphenylene oxide (PPO)). To provide better thermal performance, in some embodiments a heat spreader 218 is placed on the interior surface of the plastic back plate 206—as shown in FIG. 5. The heat spreader can be made from a thermally conductive material—such as copper sheet metal or aluminum—and the heat spreader can be thermally coupled to heat dissipating devices on the PCBA 214 using a thermal interface adhesive or gap filler materials, and as a convective heat sink to dissipate the heat to the air via the air gap between the solar shield 202 and the back plate 206 and the air gap between the back plate 206 and the mounting wall.

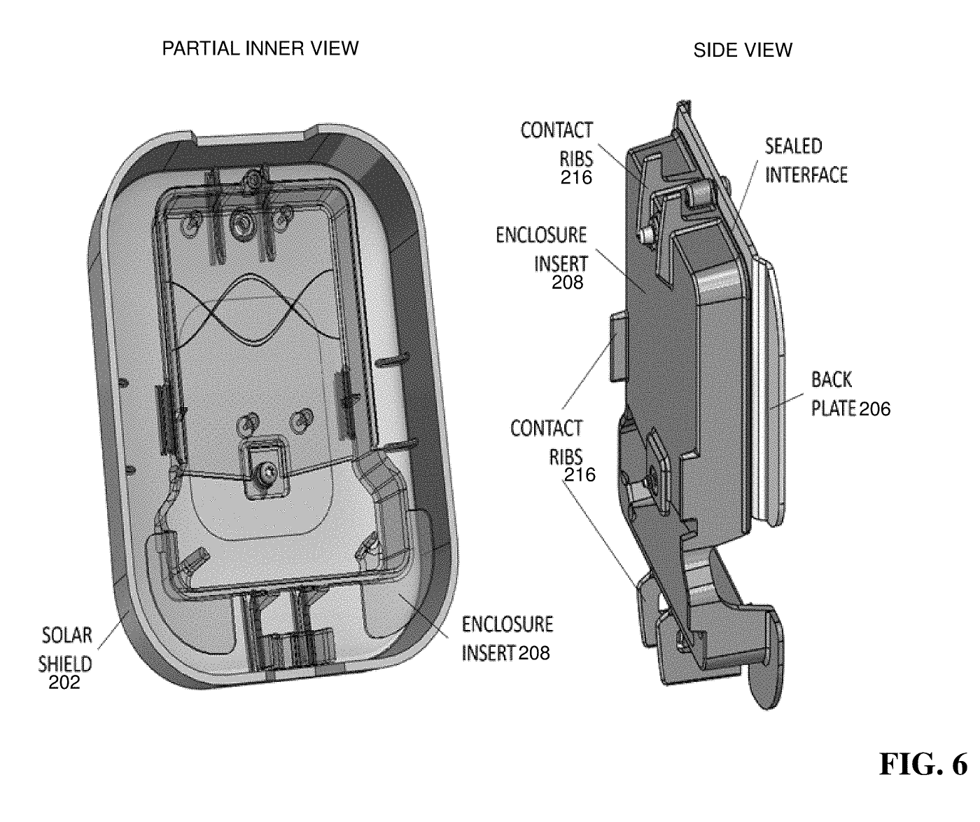

The insert 208 and back plate 206 form a sealed interface around the PCBA 214 to prevent water that might be sprayed on the mounting surface or running down the mounting wall from entering the region of the enclosure 200 that houses the PCBA 214. In some embodiments, an adhesive is dispensed between the surfaces of the insert 208 and back plate 206 before assembly to seal the interface. FIG. 6 is a diagram of a partial inner view of the electronics enclosure showing the electronics insert 208 and a side view of the electronics insert 208, according to an embodiment of the invention. As shown in FIG. 6, the insert 208 only makes contact with the solar shield 202 over narrow rib features 216 at the perimeter regions. In addition, adhesives or snap features can be integrated at the contact ribs in some embodiments to facilitate manufacturing and secure the two components together.

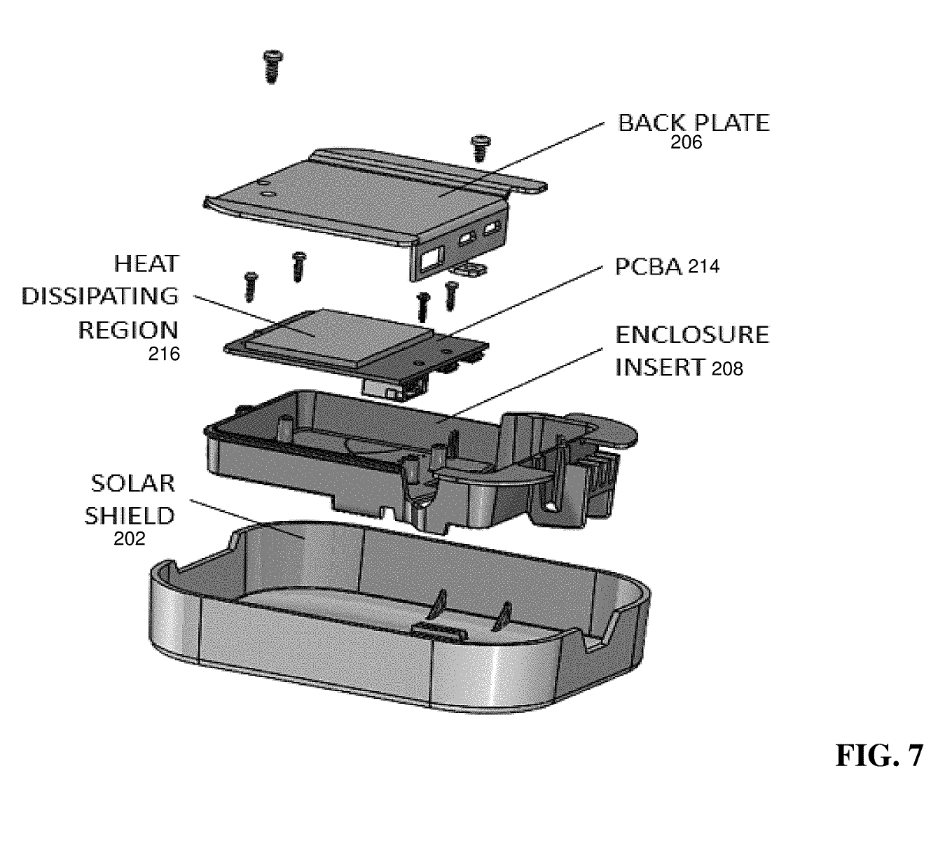

FIG. 7 is an exploded view of the electronics enclosure, according to an embodiment of the invention. As shown in FIG. 7, the components of the enclosure are secured together using screws, but other embodiments of the invention can include plastic heat stakes or snap-lock features in addition to or instead of screws. Other types of fasteners can be introduced without departing from the scope of the invention. Also, adhesive can be dispensed into the slot between the ribs on the solar shield 202 before assembling it with the insert 208.

Comprise, include, and/or plural forms of each are open ended and include the listed parts and can include additional parts that are not listed. And/or is open ended and includes one or more of the listed parts and combinations of the listed parts.

One skilled in the art will realize the invention may be embodied in other specific forms without departing from the spirit or essential characteristics thereof. The foregoing embodiments are therefore to be considered in all respects illustrative rather than limiting of the invention described herein.

What is claimed is:

1. An apparatus for thermal management and protection from moisture for an electronic device, comprising:
an internal enclosure insert containing a printed circuit board (PCB) populated with at least one electrical component;
a back plate coupled to the internal enclosure insert with an air gap to a mounting surface wall, wherein the back plate is coupled along an internal surface to at least one electrical component on the PCB; and
a thermal radiation shield coupled to and surrounding the internal enclosure insert, at least one portion of the thermal radiation shield being separated from the internal enclosure insert by at least one air gap;
wherein, when affixed to the mounting surface wall, at least one air gap is formed between the thermal radiation shield and the mounting surface.

2. The apparatus of claim 1, wherein the back plate is thermally conductive.

3. The apparatus of claim 2, wherein the back plate comprises at least one of: copper or aluminum.

4. The apparatus of claim 1, wherein the back plate is thermally insulating.

5. The apparatus of claim 4, wherein the back plate comprises plastic.

6. The apparatus of claim 5, wherein a heat spreader is placed on an interior surface of the plastic back plate.

7. The apparatus of claim 6, wherein the heat spreader comprises at least one of: copper sheet metal or aluminum.

8. The apparatus of claim 1, wherein the back plate is thermally coupled to the at least one electrical component on the PCB.

9. The apparatus of claim 8, wherein the back plate is coupled to the PCB by a thermal adhesive.

10. The apparatus of claim 1, wherein the internal enclosure insert contains a perimeter region around which a length of one or more cables is secured.

11. The apparatus of claim 10, wherein the one or more cables connect the PCB to one or more external devices.

12. The apparatus of claim 1, wherein the air gaps are sufficiently large to allow buoyancy induced natural convection.

13. The apparatus of claim 1, wherein the apparatus is part of an electrical energy monitoring system.

14. The apparatus of claim 1, wherein the apparatus is part of an outdoor telecommunications system.

15. The apparatus of claim 1, wherein the apparatus is part of an outdoor power conversion system.

16. The apparatus of claim 1, wherein the apparatus is part of an outdoor LED light fixture.
